(19) United States
(12) Patent Application Publication
(10) Pub. No.: US 2017/0271030 A1
(43) Pub. Date: Sep. 21, 2017

(54) METHOD AND SYSTEM FOR USING DOWNGRADED FLASH DIE FOR CACHE APPLICATIONS

(71) Applicant: Alibaba Group Holding Limited, Georgetown (KY)

(72) Inventor: Shu LI, Santa Clara, CA (US)

(21) Appl. No.: 15/074,961

(22) Filed: Mar. 18, 2016

(51) Int. Cl. G11C 29/42; G11C 29/44; G06F 12/08

(52) U.S. Cl. CPC G11C 29/42; G06F 12/0871; G11C 29/44; G06F 2212/1056; G06F 2212/214; G06F 2212/222; G06F 2212/281; G06F 2212/313

(57) ABSTRACT

A method and apparatus for using low-cost un-qualified dies suitable for an SSD cache application in an SSD cache are disclosed. Embodiments of the present invention enable production of a cache-die SSD with sufficient data retention and endurance to meet demands of modern data centers while reducing infrastructure costs. According to one embodiment, a method of identifying and using low-cost un-qualified dies suitable for an SSD cache application in an SSD cache is disclosed. The method includes extracting application data from the SSD cache application, modeling a behavior of the SSD cache application based on the application data, characterizing a first un-qualified die to determine at least one quantified property of the first un-qualified die, and testing the at least one quantified property of the first un-qualified die against the modeled behavior of the SSD cache application to determine if the un-qualified die is suitable for the SSD cache.

### FIELD

Embodiments of the present invention generally relate to the field of flash memory. More specifically, embodiments of the present invention relate to systems and methods for using downgraded flash dies as a cache.

### BACKGROUND

There is a growing need in the field of data storage to reduce the cost of implementing cache storage solutions to better meet the high cache demands of modern hyperscale data centers. Tiered storage solutions attempt to reach a balance between performance needs and data retention requirements of modern data centers. For example, one exemplary tiered storage path transmits data from a CPU core to various levels of caches on the CPU itself, then to DIMM memory, then to a hard disk drive for long-term storage. When the system is powered off, all data stored in the volatile memory of the DIMM and CPU cache will be lost. Therefore, for this architecture, data is always consolidated and stored in the hard disk drive for permanent/non-volatile storage. For data being transmitted upstream and downstream, data is retrieved from permanent storage, cached in memory, updated/processed by the CPU, and written back to permanent storage using the memory buffer.

While traditional tiered storage solutions offer relatively high performance and data retention, subsequent innovations have further increased the performance (e.g., throughput, IOPS, latency, etc.) of tiered storage solutions using multi-layer caches to bridge gaps between storage devices. More recently, Flash SSDs have been inserted between high-speed, low-capacity RAM and low-speed, high-capacity hard drives to further enhance performance of these systems. Flash SSDs offer a smaller footprint, lower energy consumption, higher performance, and a lower fault rate than traditional HDDs.

A Flash SSD device is typically designed for general-purpose storage, offering excellent input/output (IO) performance and years of data retention. However, when used as a cache device, data is held on the storage device for only a brief period of time before it is written to the disk for permanent storage. Therefore, traditional data retention requirements are unnecessary for cache devices. As such, general-purpose Flash SSDs are over-qualified and over-priced for use as cache devices. Data centers typically employ a vast amount of Flash SSDs thereby leading to unnecessarily high infrastructure costs. What is needed is a cache device capable of high levels of performance while lowering infrastructure costs to better meet the needs of modern hyperscale data centers.

### SUMMARY

A method and apparatus for identifying and using low-cost un-qualified dies suitable for an SSD cache application in an SSD cache are disclosed herein. Embodiments of the present invention enable production of a cache-die SSD with sufficient data retention and endurance to meet the demands of modern data centers while substantially reducing infrastructure costs thereof.

According to one embodiment, a method of identifying and using low-cost un-qualified dies suitable for an SSD cache application in an SSD cache is disclosed. The method includes extracting application data from an SSD cache application, modeling a behavior of the SSD cache application based on application data to produce a modeled behavior, characterizing a first un-qualified die to determine at least one quantified property of the first un-qualified die, and testing the at least one quantified property of the first un-qualified die against the modeled behavior of the SSD cache application to determine if the un-qualified die is suitable for use in the SSD cache.

According to some embodiments, the method described above further includes repeating the extracting, the modeling, the characterizing, and the testing until a sufficient number of un-qualified dies are identified to construct an SSD cache meeting prescribed requirements of the SSD cache application and enclosing the sufficient number of un-qualified dies in packaging to form an integrated circuit.

According to some embodiments, the method described above further includes constructing a cache-die SSD using the integrated circuit, testing the cache-die SSD against a requirement of the modeled behavior of the SSD cache application, and generating a specification of the cache-die SSD.

According to some other embodiments, the method described above further includes using corresponding device management firmware and software to control and monitor the cache-die SSD for the SSD cache application.

According to another embodiment, a solid state drive is disclosed. The solid state drive includes a plurality of un-qualified dies for storing bits of data and an SSD controller. The SSD controller includes a first interface for sending data to, and for receiving data from, the plurality of un-qualified dies, a second interface for sending data to, and for receiving data from, a CPU, a first plurality of modules coupled to the first and second interface for compressing, for encrypting, and for ECC encoding of data for storage using the plurality of un-qualified dies, and a second plurality of modules coupled to the first and second interface for ECC decoding, for decrypting, and for decompressing data retrieved from the plurality of un-qualified dies.

### BRIEF DESCRIPTION OF THE DRAWINGS:

The accompanying drawings, which are incorporated in and form a part of this specification, illustrate embodiments of the invention and, together with the description, serve to explain the principles of the invention:

FIG. 1 is a block diagram of exemplary data paths of tiered storage solutions.

FIG. 2 is a block diagram of an exemplary cache-die SSD architecture depicted according to embodiments of the present invention.

FIG. 3 is a graph of an exemplary flash programming mechanism illustrated according to embodiments of the present invention

FIG. 4 is a series of graphs depicting exemplary threshold Gaussian distributions including a programmed state and an erasure state for flash memory cells according to embodiments of the present invention.

FIG. 5 is a flowchart depicting an exemplary series of computer implemented steps of a method for testing and characterizing ink dies for use as cache-dies according to embodiments of the present invention.

### DETAILED DESCRIPTION:

Reference will now be made in detail to several embodiments. While the subject matter will be described in conjunction with the alternative embodiments, it will be understood that they are not intended to limit the claimed subject matter to these embodiments. On the contrary, the claimed subject matter is intended to cover alternative, modifications, and equivalents, which may be included within the spirit and scope of the claimed subject matter as defined by the appended claims.

Furthermore, in the following detailed description, numerous specific details are set forth in order to provide a thorough understanding of the claimed subject matter. However, it will be recognized by one skilled in the art that embodiments may be practiced without these specific details or with equivalents thereof. In other instances, well-known methods, procedures, components, and circuits have not been described in detail as not to unnecessarily obscure aspects and features of the subject matter.

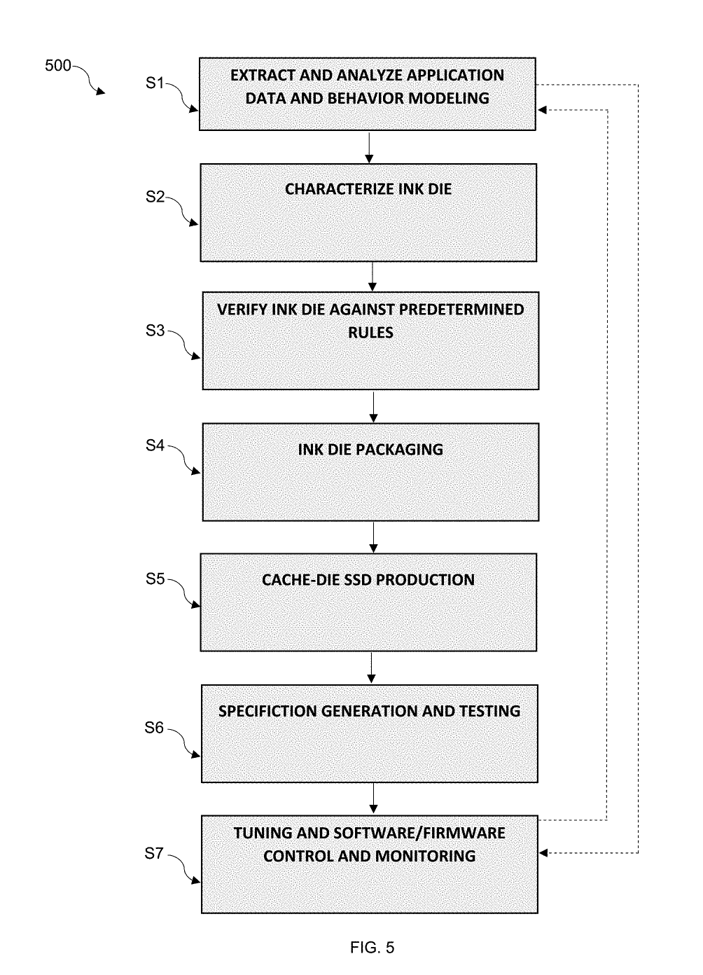

Portions of the detailed description that follow are presented and discussed in terms of a method. Although steps and sequencing thereof are disclosed in a figure herein (e.g., FIG. 5) describing the operations of this method, such steps and sequencing are exemplary. Embodiments are well suited to perform various other steps or variations of the steps recited in the flowchart of the figure herein, and in a sequence other than that depicted and described herein.

Some portions of the detailed description are presented in terms of procedures, steps, logic blocks, processing, and other symbolic representations of operations on data bits that can be performed on computer memory. These descriptions and representations are the means used by those skilled in the data processing arts to most effectively convey the substance of their work to others skilled in the art. A procedure, computer-executed step, logic block, process, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout, discussions utilizing terms such as “accessing,” “writing,” “including,” “storing,” “transmitting,” “traversing,” “associating,” “identifying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

### Downgraded Flash Die for Use In Flash SSD Cache Applications

Embodiments of the present invention describe systems and methods for implementing Flash SSD cache devices using downgraded flash dies (as called “ink dies”) to lower the cost of implementing Flash SSD caches in high-volume data storage systems. These Flash SSD cache devices offer sufficient data retention and endurance properties to meet the demands of modern data centers while substantially reducing infrastructure costs.

The downgraded dies described herein are unqualified Flash dies cut from the same wafer as qualified dies. When the dies are cut from a wafer, each die is tested to determine which if it meets all of the requirements of a qualified die. The dies that do not meet these requirements are un-qualified dies typically having one or more defects therein. Embodiments of the present invention advantageously utilize less expensive un-qualified dies that do not satisfy the data retention requirements of qualified dies. For example, dies may be classified as unqualified if they are unable to store written data for at least 12 months. When implementing a Flash SSD cache device, these data retention requirements may be waived and/or relaxed to the point where the un-qualified dies are acceptable for use.

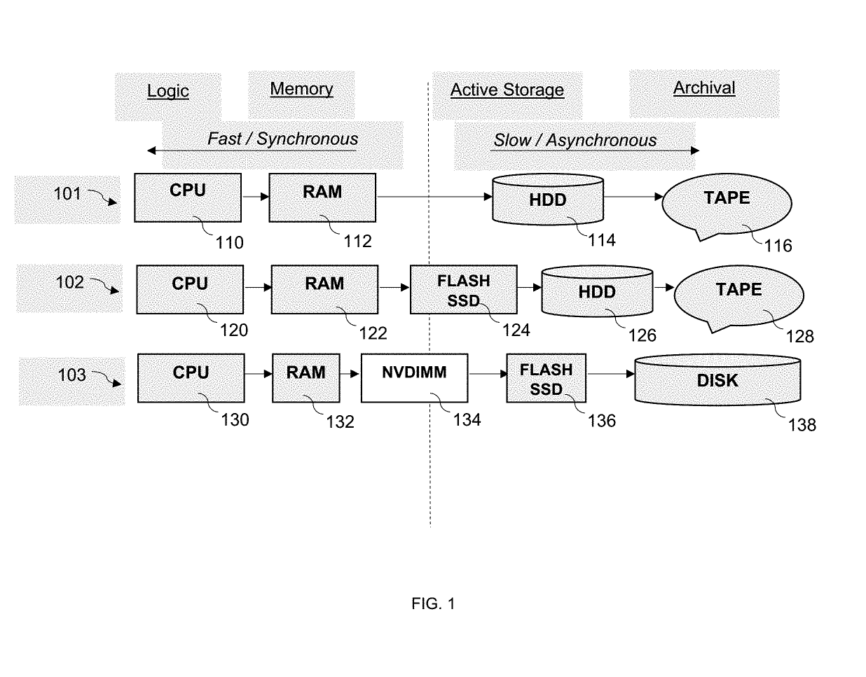

With regard to FIG. 1, exemplary data paths of tiered storage solutions are depicted according to embodiments of the present invention. Storage paths 101-103 include a CPU 110 for performing logic operations and storing small amounts of data temporarily in one or more caches of the CPU. After the data is updated/processed by the CPU, it is transmitted to RAM 112 for high-performance, low-capacity, volatile storage. Tiered storage path 101 further includes a hard disk (HDD) 114 and a tape storage device (TAPE) 116 for archival storage. Regardless of the data type or TOPS requirements, active data is always processed and accessed via disk 114. Cold data that is rarely accessed is typically moved to the tape storage device 116 and moved to the hard drive 114 when necessary.

Storage path 102 represents a more advanced storage solution comprising a Flash SSD 124 to bridge the gap between high-performance, low-capacity RAM 122 and low-performance, high-capacity HDD 126. In this configuration, the flash SSD holds data temporarily, and the data is eventually flushed to the HDD. As Flash SSDs have decreased in price, this type of storage solution is attractive due to enhanced throughput, IOPS, and enhanced capacity, for example. Recently new technology such as Non-Volatile Dual In-line Memory Module (NVDIMM) 134 has matured for use in enterprise applications to further enhance performance. Storage path 103 includes an NVDIMM 134 between the RAM 132 and Flash SSD 136 and further enhances performance of the storage path.

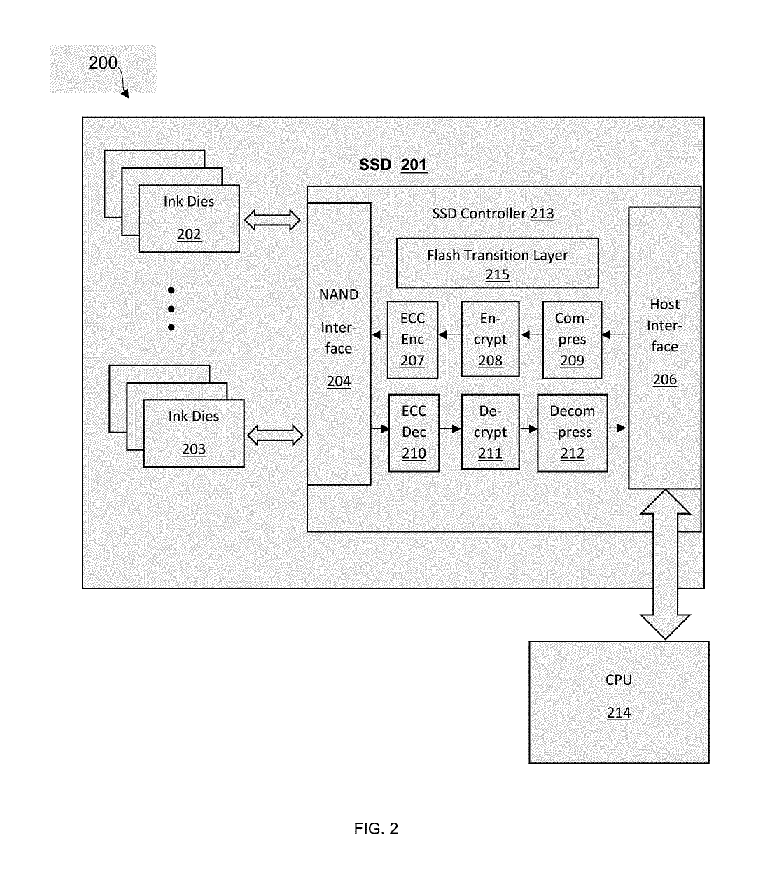

With regard to FIG. 2, an exemplary cache-die SSD architecture 200 is depicted according to embodiments of the present invention. CPU 214 sends data to SSD 201 for storage and receives data for updating/processing using Host Interface 206. Host Interface 206 may comprise a serializer/deserializer (SerDes) interface, or a Physical Interface for PCI Express Specification (PIPE) interface, for example. While triple level cell (TLC) Flash offers a much lower P/E cycle compared to multi-level cell (MLC) Flash, SSD controller 213 enhances SSD performance to a level similar to MLC Flash. A series of ink dies 202 and 203 comprising flash memory (e.g., NAND Flash) are used to store bits of data written by SSD Controller 213 using an Open NAND Flash Interface (ONFI)/Toggle interface 204. To ensure service quality when using un-qualified dies, a flexible ECC engine with adjustable error correction capability is used. Data received by Host Interface 206 is compressed by Compression Module 209, encrypted by Encryption Module 208, and encoded using an error-correcting code (ECC) by ECC Encoding Module 207. The error correction capability is enhanced do to a potentially higher error rate compared to SSD caches constructed using qualified dies. A flexible management system is used to adjust ECC Encoding Module 207 in real-time when the encoder is close to capacity. The ECC Encoding Module 207 may provide stronger error correction by lowering the encoder rate (e.g., encoding fewer bits at a time) or using more redundancy bits. The cache-die SSD architecture 200 further includes a Flash Transition Layer 215. According to some embodiments, the ECC Encoding Module 207 is adjusted based on the observed number of bits corrected in real-time.

The data is then sent to NAND Interface 204 for storage using the ink dies. SSD Controller 213 further comprises a series of modules for processing data stored on Ink Dies 202 and 203. ECC Decoder 210 receives encoded data from NAND Interface 204 and decodes the ECC encoded data. The decoded data is decrypted by Decryption Module 211 and decompressed by Decompression Module 213. The decompressed data is then passed to Host Interface 206 for retrieval by CPU 214.

SSD Controller 213 may further comprise a data flush module to copy out data from a cache-die SSD to another storage device when triggered to prevent data loss. According to some embodiments of the present invention, a timeout value is defined for a cache-die SSD. When data is stored on the cache-die SSD for longer than the timeout period, the data is automatically flushed out to a hard drive or other archival storage device. According to some embodiments, a watermark or threshold value is defined for a cache-die SSD. When the total data stored on the cache-die SSD reaches the watermark (e.g., 90% of total capacity, for instance), data is automatically flushed out to a hard drive or other archival storage device.

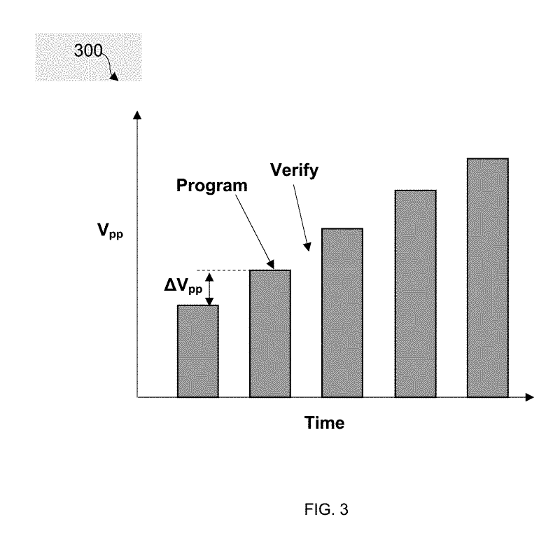

With regard to FIG. 3, a graph of an exemplary flash programming mechanism over time is illustrated according to embodiments of the present invention. A program-and-verify procedure is used to write data to the cache-die SSD, where a programmed voltage Vₚₚ is applied once, and the cell is read to determine if the threshold voltage is above a preset voltage. If the threshold voltage is lower than the preset voltage, the programming continues until the threshold voltage is determined to be higher than the preset voltage. Increasing ΔVₚₚ leads to a wider distribution of threshold voltage. Performance enhancements are implemented to tailor the cache-die SSD specifically for use as a cache. This reduces the number of program-and-verify cycles and also mitigates write latency of the cache-die SSD when a bit is programmed into the cell. The value of Vₚₚ increases each time a charge is placed on the floating gate of the NAND cells. When the programmed voltage Vₚₚ is increased by an increment of ΔVₚₚ after each write, the number of program-and-verify cycles is reduced to mitigate write latency.

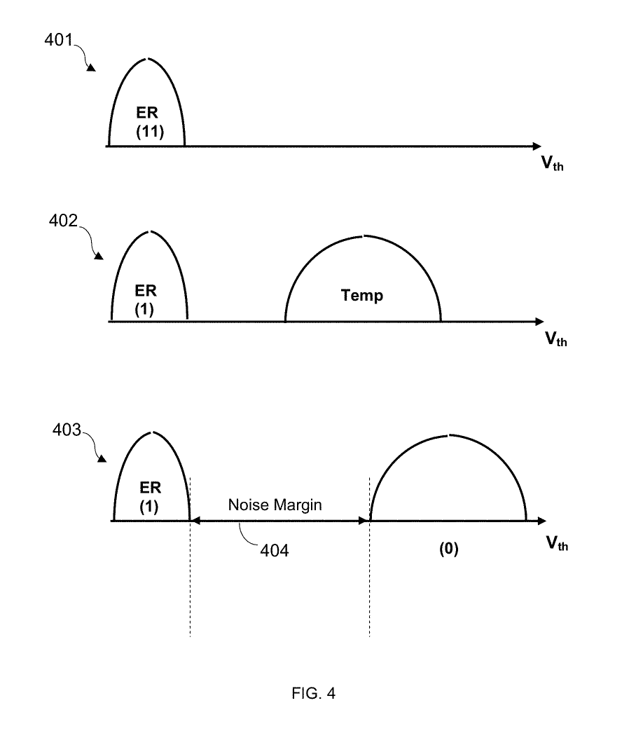

With regard to FIG. 4, a series of graphs depicting exemplary threshold Gaussian distributions for triggering a programmed state and an erasure state (“ER”) are depicted according to embodiments of the present invention. A threshold voltage in the ER range triggers the erasure state and causes a bit value of 1 to be stored in the cell. Threshold distribution 401 represents an exemplary qualified MLC NAND die with 2-bit storage per cell as used in a general purpose SSD. Threshold distribution 402 represents a qualified die having 1-bit storage per cell with a standard noise margin. Threshold distribution 403 represents an un-qualified die having 1-bit storage per cell with an increased noise margin 404. With this wider threshold distribution, a program state that causes a bit value of 0 to be stored is located further along the Vₜₕ axis. The noise margin 404 should be large enough to handle the signal-to-noise ratio for the short period of time that data is held in the cache-die SSD. In general, a larger gap between the program state and the erasure state will lower the expected bit error rate. The cache-die is tested to ensure that data can be retrieved from the cache-die before the data is lost due to excessive noise.

With regard to FIG. 5, a flowchart depicting a series of computer implemented steps of a method 500 for testing and characterizing ink dies for use as cache-dies is depicted according to embodiments of the present invention. This SSD and application development method forms a closed loop and may be used to iteratively perform hardware and software optimizations to promote efficiency.

At step S1, online application data is extracted and analyzed to model the behavior of a given application for recursive modeling (e.g., required data retention, number of reads before data is copied out, and how much valid data is held in a cache-SSD when a page is written). At step S2, characterization of an ink die is extracted and various properties are quantified, such as, but not limited to data retention, program/erase cycle, and temperature range. At step S3, the quantified properties are tested against a predetermined set of rules based on the specific application to verify the ink die (e.g., determine if the ink die is suitable for use in the SSD cache). Ink dies that meet the set of predetermined rules may be used as cache dies. At step S4, multiple cache dies are enclosed together in a package to form an integrated circuit (e.g., a NAND flash chip). At step S5, the integrated circuit is used to construct a cache-die SSD. At step S6, the cache-die SSD is thoroughly tested using a series of programs, and a specification of the cache-die SSD is generated. At step S7, the application is tuned to ensure compatibility with the cache-die SSD, and corresponding device management firmware and software are used to control and monitor the cache-die SSD.

Steps S1 and S7 of method 500 may be repeated to recursively optimize the hardware and software and ensure a seamless data path. The entire process S1-S7 may be repeated until the application requirements are satisfied.

Embodiments of the present invention are thus described. While the present invention has been described in particular embodiments, it should be appreciated that the present invention should not be construed as limited by such embodiments, but rather construed according to the following claims.

What is claimed is:

1. A method of identifying and using un-qualified dies suitable for an SSD cache application in an SSD cache, the method comprising:
extracting application data from the SSD cache application;
modeling a behavior of the SSD cache application based on the application data to produce a modeled behavior;
characterizing a first un-qualified die to determine at least one quantified property of the first un-qualified die; and
testing the at least one quantified property of the first un-qualified die against the modeled behavior of the SSD cache application to determine if the un-qualified die is suitable for use in the SSD cache.

2. The method of claim 1, further comprising repeating the extracting, the modeling, the characterizing, and the testing until a sufficient number of un-qualified dies are identified to construct an SSD cache meeting prescribed requirements of the SSD cache application.

3. The method of claim 2, further comprising enclosing the sufficient number of un-qualified dies in packaging to form an integrated circuit.

4. The method of claim 3, further comprising constructing a cache-die SSD using the integrated circuit, wherein the cache-die SSD meets a requirement of the modeled behavior of the SSD cache application.

5. The method of claim 3, further comprising:
constructing a cache-die SSD using the integrated circuit;
testing the cache-die SSD against a requirement of the modeled behavior of the SSD cache application; and
generating a specification of the cache-die SSD.

6. The method of claim 5, further comprising tuning the SSD cache application for compatibility with the cache-die SSD.

7. The method of claim 6, further comprising using corresponding device management firmware and software to control and monitor the cache-die SSD for the SSD cache application based on the modeled behavior.

8. The method of claim 3, wherein the un-qualified die comprises a NAND Flash die.

9. The method of claim 3, wherein the un-qualified die is characterized as having an increased noise margin to reduce an error rate of the un-qualified die.

10. The method of claim 3, wherein the un-qualified die is characterized in that a programmed voltage value of the un-qualified die is increased when a charge is placed on a floating gate thereof to mitigate write latency.

11. A solid state drive comprising:
a plurality of un-qualified dies for storing data; and
an SSD controller, comprising:
a first interface for sending data to and receiving data from the plurality of un-qualified dies;
a second interface for sending data to and receiving data from a CPU;
a first plurality of modules coupled to the first and second interfaces, the first plurality of modules for compressing, for encrypting, and for ECC encoding data for storage using the plurality of un-qualified dies; and
a second plurality of modules coupled to the first and second interfaces, the second plurality of modules for ECC decoding, for decrypting, and for decompressing data retrieved from the plurality of un-qualified dies.

12. The solid state drive of claim 11, wherein the plurality of un-qualified dies comprises NAND Flash and the first interface is a NAND Flash interface.

13. The solid state drive of claim 11, wherein the ECC encoding comprises adjustable, on-the fly ECC encoding based on an observed error rate of the plurality of un-qualified dies.

14. The solid state drive of claim 13, wherein the adjustable, on-the fly ECC encoding is configured to use a greater number of redundancy bits when the observed error rate exceeds a threshold.

15. The solid state drive of claim 13, wherein the adjustable, on-the fly ECC encoding is configured to encode fewer bits when the observed error rate exceeds a threshold.

16. The solid state drive of claim 11, wherein the plurality of un-qualified dies comprises an increased noise margin to reduce an error rate thereof.

17. The solid state drive of claim 11, wherein the plurality of un-qualified dies is characterized in that a programmed voltage value of the plurality of un-qualified dies is increased when a charge is placed on a floating gate thereof to mitigate write latency.

18. A cache-die SSD architecture comprising:
a PIPE interface configured to communicate with a CPU;
a NAND interface communicatively coupled to a plurality of un-qualified NAND cache dies; and
an adjustable ECC encoding module coupled to the PIPE interface and the NAND interface, wherein the adjustable ECC encoding module automatically adjusts an encoding rate thereof based on an observed error rate of the plurality of un-qualified NAND cache dies and uses an increased number of redundancy bits when the observed error rate reaches a predetermined threshold.

19. The cache-die SSD architecture of claim 18, further comprising an encryption module communicatively coupled to the PIPE interface and the ECC encoding module, wherein data received by the PIPE interface is encrypted by the encryption module before being sent to the ECC encoding module.

20. The cache-die SSD architecture of claim 19, further comprising a compression module communicatively coupled to the PIPE interface and the encryption module, wherein data received by the PIPE interface is compressed by the compression module before being sent to the encryption module.
